(19) United States
(12) Patent Application Publication
(10) Pub. No.: US 2003/0124865 A1
(43) Pub. Date: Jul. 3, 2003

(54) Method for forming pattern using printing process

(75) Inventors: Myoung-Kee Baek, Seoul (KR); Yong-Jin Cho, Seoul (KR)

Correspondence Address: MORGAN LEWIS & BOCKIUS LLP, 1111 PENNSYLVANIA AVENUE NW, WASHINGTON, DC, 20004, US

(73) Assignee: LG. Philips LCD Co., Ltd.

(21) Appl. No.: 10/325,841

(22) Filed: Dec. 23, 2002

(30) Foreign Application Priority Data
Dec. 28, 2001 (KR) 87439/2001

(51) Int. Cl. H01L 21/311; H01L 21/461

(52) U.S. Cl. 438/694; 438/780; 438/725

(57) ABSTRACT

A method for forming a pattern includes filling resist in a recess of a cliché corresponding to a position of a pattern to be formed, transferring the resist filled in the recess onto a surface of a transfer roll by rotating the transfer roll on the cliché, forming a resist pattern by rotating the transfer roll onto a process-subjected layer such that the transfer roll contacts the process-subjected layer of a substrate, ashing resist residuals from the substrate on which the resist pattern is formed using a plasma, and etching the process-subjected layer using one of dry etching and wet etching.

The present invention claims the benefit of Korean Patent Application No. 87439/2001 filed in Korea on Dec. 28, 2001, which is hereby incorporated by reference.

### BACKGROUND OF THE INVENTION

1. Field of the Invention

The present invention relates to a method for forming a pattern, and particularly, to a method for forming a pattern capable of preventing pattern inferiority due to residue in forming the pattern.

2. Discussion of the Related Art

Display devices, especially flat panel display devices, such as a liquid crystal display devices, comprise an active device such as a thin film transistor formed on a respective pixel to drive the display device. The method for driving display devices such as the one referenced above is referred to as active matrix driving method. In this active matrix method, the active devices are placed on the respective pixels arranged in a matrix form to drive the corresponding pixels.

FIG. 1 is a schematic view of a liquid crystal display (LCD) device of the active matrix type according to the related art. FIG. 1 shows a TFT LCD having a thin film transistor (TFT) as the active device. As shown in FIG. 1, the respective pixel of the TFT LCD having the pixels of N×M disposed in longitudinal and transverse directions includes the TFT which is formed at a crossed region of a gate line 4, to which a scan signal is applied, and a data line 6, to which an image signal is applied. The TFT comprises a gate electrode 3 connected to the gate line 4, a semiconductor layer 8 formed on the gate electrode 3 and activated as the scan signal is applied to the gate electrode 3, and source/drain electrodes 5 formed on the semiconductor layer 8. A pixel electrode 10 connected to the source/drain electrodes 5 to operate liquid crystal (not shown) by applying the image signal through the source/drain electrodes 5 as the semiconductor layer 8 is activated is formed on a display area of the pixel 1.

FIG. 2 is a cross sectional view of a TFT disposed in the respective pixel according to the related art. As shown in FIG. 2, the TFT comprises a substrate 20 made of a transparent insulating material such as a glass, a gate electrode 3 formed on the substrate 20, and a gate insulating layer 22 formed over the entire substrate. The TFT also comprises a semiconductor layer 6 formed on the gate insulating layer 22 activated as a signal and applied to the gate electrode 3, a source electrode 5, and a drain electrode 9 over the semiconductor layer 6. A passivation layer 25 is formed over the source electrode 5 and the drain electrode 9 to protect the device. The source electrode 5 and the drain electrode 9 are electrically connected to the pixel electrode formed in the pixel, and drive the liquid crystal as a signal is applied to the pixel electrode through the source electrode 5 and the drain electrode 9, thereby displaying an image.

In the above active matrix type display, a size of the respective pixel is tens of μm, therefore, the active device such as the TFT disposed in the pixel should be a few μm. Moreover, as requirements for high image quality display devices such as HDTV's have recently increased, more pixels need to be disposed on a screen of the same area. Therefore, the size of the active device patterns (including the gate line and data line patterns) disposed in the pixel should be decreased.

On the other hand, in order to fabricate the active device such as the TFT according to the related art, a pattern or a line of the active device is formed by a photolithography method using a light exposure device. In this photolithography method, a photoresist is laminated on a patterned layer, and thereafter an etching method by a photo process is performed. However, since photo devices are expensive, fabrication costs are increased and fabrication processes become complex. Moreover, since an exposure area of an exposing device is limited during the photo process of the display device, the photo process needs to be performed by dividing a screen in order to fabricate the display device of larger area. Therefore, it is difficult to precisely match these divided areas, and also, productivity is lowered by repeated photo processes.

### SUMMARY OF THE INVENTION

Accordingly, the present invention is directed to a method for forming a pattern that substantially obviates one or more of the problems due to limitations and disadvantages of the related art.

Another object of the present invention is to provide a method for forming a pattern having simple fabrication processes and low fabrication costs by forming a resist pattern on a process-subjected layer formed on a substrate in a simple printing method.

Another object of the present invention is to provide a method for forming a pattern capable of preventing defective patterns by ashing remaining resist residual on undesired areas in the resist printing process by a dry etching process using plasma.

Still another object of the present invention is to provide a method for forming a pattern which is able to form fine pattern by etching a resist pattern in a dry etching method using a plasma.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, the method for forming a pattern includes filling resist in a recess of a cliché corresponding to a position of a pattern to be formed, transferring the resist filled in the recess onto a surface of a transfer roll by rotating the transfer roll on the cliché, forming a resist pattern by rotating the transfer roll onto a process-subjected layer such that the transfer roll contacts the process-subjected layer of a substrate, ashing resist residuals from the substrate on which the resist pattern is formed using a plasma, and etching the process-subjected layer by applying an etchant to the substrate on which the resist pattern is formed.

In another aspect of the present invention, a method for forming a pattern includes the steps of forming a resist pattern by printing a resist on a process-subjected layer formed on a substrate, ashing resist residuals on the substrate on which the resist pattern is formed using a plasma, and etching the process-subjected layer by applying an etchant to the substrate on which the resist pattern is formed.

In another aspect of the present invention, a method for forming a pattern includes the steps of filling resist in a recess of a cliché corresponding to a position of a pattern which will be formed, transferring the resist filled in the recess onto a surface of a transfer roll by rotating the transfer roll on the cliché, forming a resist pattern by rotating the transfer roll onto a process-subjected layer such that the transfer roll contacts the process-subjected layer of a substrate, controlling a line width of the resist pattern by etching both side surfaces of the resist pattern using a plasma, and etching the process-subjected layer by applying an etchant on the substrate on which the resist pattern is formed.

In another aspect of the present invention, a method for forming a pattern includes the steps of forming a resist pattern by printing a resist on a process-subjected layer formed on a substrate, controlling a line width of the resist pattern by etching both side surfaces of the resist pattern using plasma, and etching the process-subjected layer by applying an etchant on the substrate on which the resist pattern is formed.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a plane view of a liquid crystal display (LCD) device according to the related art;

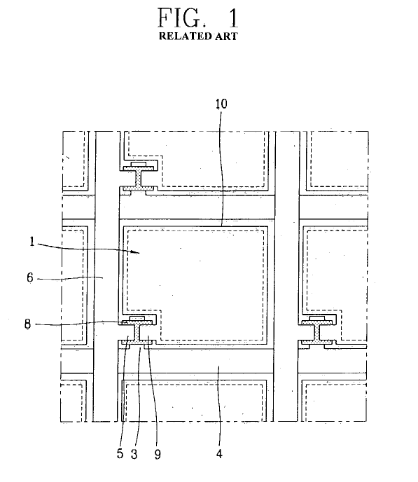

FIG. 2 is a cross sectional view of a thin film transistor shown in FIG. 1 according to the related art;

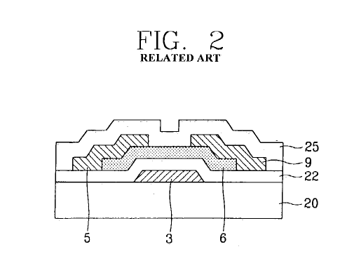

FIGS. 3A-3D are cross sectional views of an exemplary method for forming a pattern using a gravure printing method according to the present invention;

FIG. 4A is a cross sectional view of residual resist remaining on a substrate in gravure printing according to present invention;

FIG. 4B is a cross sectional view of an inferior pattern due to residual resist when pattern is formed by the gravure printing according to present invention;

FIG. 5 is a schematic view of an exemplary method for ashing the residual resist by a dry etching method using plasma in the method for forming pattern according to the present invention; and

FIG. 6 is a cross sectional view of an exemplary method for fine pattern by dry etching according to the present invention.

### DETAILED DESCRIPTION OF THE PREFERRED EMBODIMENTS

Reference will now be made in detail to the preferred embodiments of the present invention, examples of which are illustrated in the accompanying drawings.

In the present invention, where an active device pattern of a display device is formed by a printing method, residuals except printed resist pattern undergo an ashing process by a dry etching method using plasma. There may be a plurality of printing methods. In the present invention, a gravure printing method is used as an example among the printing methods, however, the present invention can be applied to various printing methods as well as the gravure printing method.

The gravure printing method is a printing method where a concave plate is stained with ink and printed after raking out any surplus ink. This method can be used in various fields such as publication, packing, cellophane, vinyl, and polyethylene. In the present invention, the active device or a circuit pattern applied to the display device is fabricated using the printing method.

In the gravure printing method, since the ink is transferred onto a substrate using a transfer roll, a pattern can be formed in one attempt by transferring the pattern. This can be done even to a display device of larger area by using a transfer roll having a size corresponding to an area of the display device. The above gravure printing method can be used for patterning various patterns in the display device, such as a thin film transistor (TFT), a gate line and a data line connected to the TFT, a pixel electrode, and a metal pattern for capacitor in case of the LCD device. Also, the gravure printing method can be used for forming various electrodes and metal patterns of a semiconductor device.

Hereinafter, a method for forming a pattern according to the present invention will be described in detail with reference to accompanying FIGs.

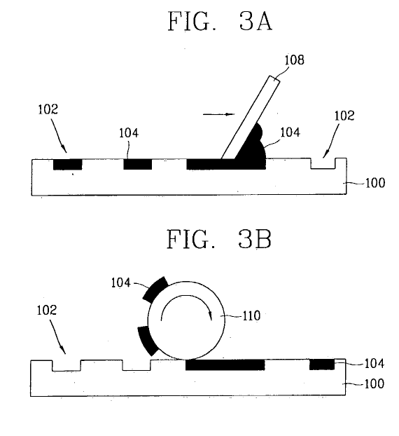

FIGS. 3A-3D are cross sectional views of an exemplary method for forming a pattern using a gravure printing method according to the present invention. As shown in FIG. 3A, in the gravure printing method, a recess 102 may be formed on a certain position of a concave plate or a cliche 100 corresponding to a pattern that will be formed on the substrate, and then, resist 104 may be filled in the recess 102. The recess 102 formed on the cliche 100 may be formed by a general photolithography method or in a mechanical way, and the filling of resist into the recess 102 may be made by moving a doctor blade 108 along the cliche 100 after applying the resist 104 on an upper part of the cliche 100. Therefore, the resist 104 may be filled in the recess 102 and at the same time, the remaining resist 104 on the surface of cliche 100 may be removed by moving the doctor blade 108.

In FIG. 3B, the resist 104 filled in the recess 102 of the cliche 100 may be being transferred onto a surface of a transfer roll 110 that rotates and contacts the surface of cliche 100. The transfer roll 110 may be formed to have the same width as a width of a panel in the display device which will be fabricated, and a circumference the same as the length of the panel. Thus, the resist 104 formed in the recess 102 of the cliche 100 may be transferred onto the circumferential surface of the transfer roll on one rotation.

FIG. 3C shows the transfer roll 110 rotating and contacting the surface of a process-subjected layer 121 formed on the substrate 120, and transferring the resist 104 onto the process-subjected layer 121. Thereafter, the transferred resist 104 may be heat dried forming a resist pattern 122. At that time, the desired pattern may be formed throughout the entire substrate 120 in one rotation of the transfer roll 110. During the gravure printing method, the cliche 100 and the transfer roll 110 may be fabricated according to the desired size of display device, and the pattern can be formed on the entire substrate 120 in one rotation. Thus, the pattern in a display device of larger area may be formed in one process. The process-subjected layer 121 may be a metal layer for forming electrodes, such as a gate electrode, source/drain electrodes, a gate line, a data line or a pixel electrode of the TFT, or may be an insulating layer, such as SiOx or SiNx.

FIG. 3D shows a desired pattern 132 formed by dry-etching or wet-etching the process subjected layer 121 except at the location where the resist pattern 122 was formed.

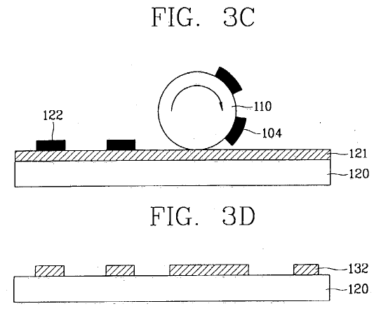

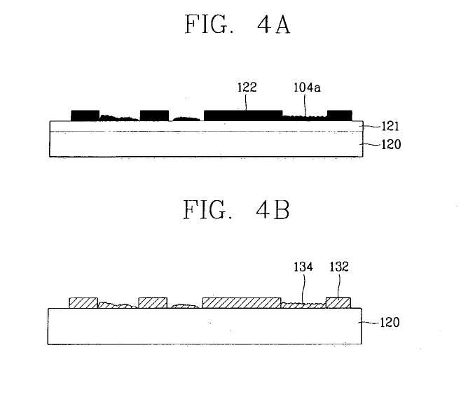

As described above, the gravure printing method has many advantages since the resist pattern may be formed in one process on the display device of larger area by the gravure printing method. However, there may be problems in the method for forming the pattern using the gravure printing method as follows. First, when the resist 104 of the transfer roll 110 is re-transferred onto the substrate 120, residues of the resist 104 may remain on the transfer roll 110. As shown in FIG. 4A, if the residue of the resist 104 on the transfer roll 110 is re-transferred onto the substrate 120 when the next printing process is performed, the residual resist 104a may remain and accumulate on unwanted areas of the substrate 120 as well as the resist pattern 122. Accordingly, as shown in FIG. 4B, if the pattern 132 of the display device is formed using the resist pattern 122, an unnecessary pattern 134 may be formed on the area where the resist residual remained, and thus blots may be generated on a screen when the display device is fabricated and the metal pattern 132 may be even shorted when the TFT metal pattern is formed. In order to solve the problem, the surface of the transfer roll 110 may be cleaned before every process. However, it may not be possible to clean the transfer roll 110 completely, and it is cleaning the transfer roll 110 before every process may be inconvenient.

Second, the method for forming the pattern using the gravure printing method uses mechanical devices, such as the cliche 100 and the transfer roll 110. Accordingly, it may be difficult to form fine patterns by photolithographic processes using photo devices. In the method for forming pattern according to the present invention, an ashing of unnecessary residual resist is made using a dry etching method, and some of the resist pattern may be etched to form the resist pattern of small line width.

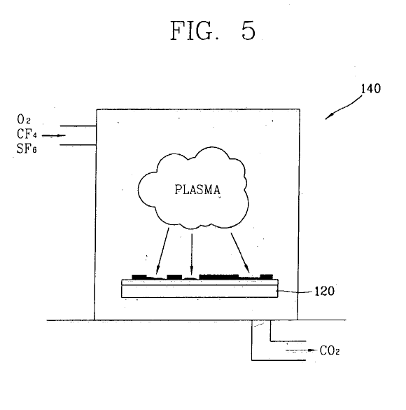

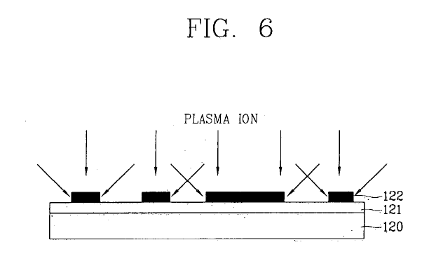

FIG. 5 is a schematic view of an exemplary method for ashing the residual resist by a dry etching method using plasma in the method for forming pattern according to the present invention. As shown in FIG. 5, the ashing process may take place in a vacuum chamber 140. The substrate 120 on which the resist pattern 140 is formed may be installed into the vacuum chamber 140, and gas may be is supplied into the vacuum chamber 140. Oxygen (O₂) may be used as the gas supplied into the vacuum chamber, and inert gas, such as CF₄ or SF₆ may be added. Although not shown in FIG. 6, an electrode may bes installed within the vacuum chamber 140 to apply high voltage into the vacuum chamber 140 from an electric source on an outer part. As the high voltage is applied, the O₂ gas supplied into the vacuum chamber 140 generates a plasma, and positive ions in plasma states are accelerated and collide into the residual resist on the substrate 120. The plasma positive ions and the resist residual are chemically combined by the collisions and generate CO₂ gas. In addition, the generated CO₂ gas is discharged to an outer side and the resist residual remaining on the substrate 120 is completely removed.

The plasma ions that collide into the process-subjected layer 121, such as the metal layer and the process-subjected layer 121, may be etched by combining with the plasma ions. However, in the present invention, O₂ gas may be supplied into the vacuum chamber 140 to prevent the process-subjected layer 121, especially the metal layer, from being chemically combined with the plasma ions, thereby etching of the process-subjected layer 121 may be prevented.

The resist pattern 122 formed on the substrate 120 may be etched during ashing process by the plasma. However, since the thickness of the resist pattern 122 formed on the substrate 120 may be about a few μm and the thickness of the resist residual may be about hundreds˜thousands of A, the thickness of the resist pattern 122 etched by the dry etching may be only about hundreds˜thousands of Å. Accordingly, the etched thickness of the resist pattern may be very small compared to the entire thickness of the resist pattern 122. Thus, even though a small portion of the resist pattern may be removed, there is no problem to use the resist pattern 122 as a blocking layer for forming pattern. Consequently, the above dry etching method using the plasma may be able to perform the ashing of the resist residual remaining on the substrate 120 effectively, and an inferior pattern may be prevented when the pattern is formed by post-processing.

The dry etching using the plasma can be used for forming fine patterns. Generally, is it very difficult to form fine patterns using the gravure printing due to structural characteristics of the printing method. However, some of the resist pattern is etched using the plasma, and thereby finer patterns than the resist pattern formed by the gravure printing may be formed. The method for forming the fine patterns is shown in FIG. 6.

FIG. 6 is a cross sectional view of an exemplary method for fine pattern by dry etching according to the present invention. As shown in FIG. 6, when the plasma ions are applied to the substrate 120 on which the resist pattern 122 is formed, the plasma ions collide into the side surfaces of the resist pattern 122 as well as the upper surface of the resist pattern 122. Thus, the resist on the upper and side surfaces of the resist pattern 122 may be removed by chemical binding. Etching rates of the upper surface and the side surface of the resist pattern 122 by the dry etching would be similar to each other. That is, the side surface and the upper surface of the resist pattern 122 may be etched nearly at the same rate as each other by the operation of the plasma ions. Thus, the resist pattern 122 may be finely formed by the side surface etching. However, the upper surface of the resist pattern 122 may also be etched such that an inferior pattern may be generated. Accordingly, the object of the present invention is to form relatively finer patterns by processing the resist pattern 122 that is already formed by the printing method. Thus, in the present invention, the resist pattern 122 of thousands of A of the resist pattern 122 may be etched, and the pattern inferiority due to the etching of resist pattern 122 may not be generated.

As described, the resist pattern 122 may be dry etched by the plasma ions, and thereby the resist pattern 122 having much finer line width may be formed, and consequently, the fine metal pattern may be formed.

It will be apparent to those skilled in the art that various modifications and variations can be made in the method for forming a pattern using the printing method of the present invention without departing from the spirit or scope of the invention. Thus, it is intended that the present invention cover the modifications and variations of this invention provided they come within the scope of the appended claims and their equivalents.

What is claimed is:

1. A method for forming a pattern, comprising the steps of:
filling resist in a recess of a cliché corresponding to a position of a pattern to be formed;
transferring the resist filled in the recess onto a surface of a transfer roll by rotating the transfer roll on the cliché;
forming a resist pattern by rotating the transfer roll onto a process-subjected layer such that the transfer roll contacts the process-subjected layer of a substrate;
ashing resist residuals from the substrate on which the resist pattern is formed using a plasma; and
etching the process-subjected layer.

2. The method according to claim 1, wherein the process-subjected layer includes a metal layer.

3. The method according to claim 1, wherein the step of ashing the resist residuals includes the steps of:
placing the substrate on which the resist is transferred into a gas-filled vacuum chamber;
generating a plasma by applying high voltage to the gas; and
removing the resist residuals by colliding ions of plasma onto the resist residuals.

4. The method according to claim 3, wherein the gas is O₂.

5. The method according to claim 4, wherein one of CF₄ and SF₆ is added to the gas.

6. A method for forming a pattern, comprising the steps of:
forming a resist pattern by printing a resist on a process-subjected layer formed on a substrate;
ashing resist residuals on the substrate on which the resist pattern is formed using a plasma; and
etching the process-subjected layer.

7. A method for forming a pattern, comprising the steps of:
filling resist in a recess of a cliché corresponding to a position of a pattern which will be formed;
transferring the resist filled in the recess onto a surface of a transfer roll by rotating the transfer roll on the cliché;
forming a resist pattern by rotating the transfer roll onto a process-subjected layer such that the transfer roll contacts the process-subjected layer of a substrate;
controlling a line width of the resist pattern by etching both side surfaces of the resist pattern using a plasma; and
etching the process-subjected layer.

8. The method of claim 7, wherein a width of an etched resist pattern is less than a thickness of the resist pattern.

9. The method of claim 7, wherein the process-subjected layer includes a metal layer.

10. The method of claim 7, wherein the step of etching the resist pattern includes the steps of:
placing the substrate having the resist formed thereon into a gas-filled vacuum chamber;
generating a gas plasma by applying high voltage to the gas; and
etching the resist pattern by colliding ions of plasma states onto the resist pattern.

11. The method of claim 10, wherein the gas is O₂ gas.

12. The method of claim 11, wherein one of CF₄ and SF₆ is added in the gas.

13. A method for forming a pattern, comprising the steps of:
forming a resist pattern by printing a resist on a process-subjected layer formed on a substrate;
controlling a line width of the resist pattern by etching side surfaces of the resist pattern using plasma; and
etching the process-subjected layer.
